(19) United States
(12) Patent Application Publication
(10) Pub. No.: US 2025/0324572 A1
(43) Pub. Date: Oct. 16, 2025

(54) SEMICONDUCTOR MEMORY DEVICE

(71) Applicant: SAMSUNG ELECTRONICS CO., LTD., Suwon-si (KR)

(72) Inventors: Seo Hyeong JANG, Suwon-si (KR); Yeon Ju OH, Suwon-si (KR); Su Hyun KIM, Suwon-si (KR); Ji Hoon KIM, Suwon-si (KR); Hong Min SEO, Suwon-si (KR); Dong Ju CHANG, Suwon-si (KR)

(73) Assignee: SAMSUNG ELECTRONICS CO., LTD., Suwon-si (KR)

(21) Appl. No.: 19/007,233

(22) Filed: Dec. 31, 2024

(30) Foreign Application Priority Data
Apr. 12, 2024 (KR) 10-2024-0049282

(51) Int. Cl. H10B 12/00; H10D 64/66; H10D 64/68

(52) U.S. Cl. CPC H10B 12/482; H10B 12/315; H10B 12/485; H10B 12/488; H10D 64/665; H10D 64/693

(57) ABSTRACT

A semiconductor memory device includes a gate structure in a gate trench. The gate structure includes: a gate insulating film extending along the gate trench; a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; and a gate electrode pattern in the gate recess and contacting the upper surface of the gate conductive film. The gate electrode pattern includes a first portion in the gate recess, and a second portion on the first portion of the gate electrode pattern. The second portion of the gate electrode pattern is in contact with the upper surface of the gate conductive film.

### CROSS-REFERENCE TO RELATED APPLICATION

This application claims priority from Korean Patent Application No. 10-2024-0049282, filed on Apr. 12, 2024, in the Korean Intellectual Property Office, the disclosure of which is incorporated by reference herein in its entirety.

### BACKGROUND

### 1. Technical Field

The present disclosure relates to a semiconductor memory device, and more specifically, to a semiconductor memory device including a buried channel array transistor (BCAT).

### 2. Description of Related Art

As a semiconductor device becomes increasingly highly integrated, individual circuit patterns are becoming smaller in order to implement a greater number of semiconductor devices in the same area.

In a highly scaled semiconductor device, word-line resistance may increase. The increase in the word-line resistance may adversely affect transistor characteristics. Accordingly, there is a need to reduce the word-line resistance.

### SUMMARY

One or more embodiments provide a semiconductor memory device having improved reliability and performance.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using features shown in the claims or combinations thereof.

According to an aspect of an embodiment, a semiconductor memory device includes: a substrate including an element isolation film and an active area defined by the element isolation film; a gate structure in a gate trench in the substrate which extends across the element isolation film and the active area in a first direction. The gate structure includes: a gate insulating film extending along the gate trench; a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; and a gate electrode pattern in the gate recess and contacting the upper surface of the gate conductive film. The gate electrode pattern includes a first portion in the gate recess, and a second portion on the first portion of the gate electrode pattern. The second portion of the gate electrode pattern is in contact with the upper surface of the gate conductive film. The first portion of the gate electrode pattern includes a plurality of first conductive material crystals having a crystal orientation corresponding to a second direction. The second portion of the gate electrode pattern includes a plurality of second conductive material crystals having a crystal orientation corresponding to a third direction.

According to an aspect of an embodiment, a semiconductor memory device includes: a substrate including an element isolation film and an active area defined by the element isolation film; and a gate structure in a gate trench in the substrate which extends across the element isolation film and the active area in a first direction. The gate structure includes: a gate insulating film extending along the gate trench; a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; and a gate electrode pattern in the gate recess and contacting the upper surface of the gate conductive film. The gate electrode pattern includes a first portion in the gate recess, and a second portion on the first portion of the gate electrode pattern. The second portion of the gate electrode pattern is in contact with the upper surface of the gate conductive film. The first portion of the gate electrode pattern includes a plurality of first conductive material crystals stacked in a second direction. The second portion of the gate electrode pattern includes a plurality of second conductive material crystals arranged in a third direction.

According to an aspect of an embodiment, a semiconductor memory device includes: a substrate including an active area defined by an element isolation film, wherein the active area extends in a first direction, and includes a first portion, and second portions respectively defined on opposite sides of the first portion; a word-line in the substrate and the element isolation film, wherein the word-line extends in a second direction different from the first direction across an area between the first portion of the active area and one of the second portions of the active area; a bit-line contact connected to the first portion of the active area; a bit-line on the bit-line contact and connected to the bit-line contact, wherein the bit-line extends in a third direction different from the first direction and the second direction; a storage contact connected to one of the second portions of the active area; a landing pad on the storage contact and connected to the storage contact; and a capacitor on the landing pad and connected to the landing pad. The word-line includes a gate structure in a gate trench. The gate structure includes: a gate insulating film extending along the gate trench; a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; a gate electrode pattern in the gate recess and contacting the upper surface of the gate conductive film; and a gate capping film on the gate electrode pattern. The gate electrode pattern includes a first portion in the gate recess, and a second portion on the first portion of the gate electrode pattern. The second portion of the gate electrode pattern is in contact with the upper surface of the gate conductive film. The first portion of the gate electrode pattern includes a plurality of first conductive material crystals having a crystal orientation corresponding to the third direction. The second portion of the gate electrode pattern includes a plurality of second conductive material crystals having a crystal orientation corresponding to a fourth direction.

### BRIEF DESCRIPTION OF DRAWINGS

The above and other object, features and advantages will be more from the following description of embodiments, taken in conjunction with the attached drawings, in which:

FIG. 1 is a schematic layout diagram of a semiconductor memory device according to some embodiments.

FIG. 2 is a layout diagram showing a word-line and an active area of a semiconductor memory device according to some embodiments.

FIG. 3 is a cross-sectional view cut along A-A in FIG. 1 according to some embodiments. embodiments.

FIG. 4 is a cross-sectional view cut along B-B in FIG. 1 according to some

FIG. 5 is a cross-sectional view cut along C-C in FIG. 1 according to some embodiments.

FIG. 6 is a cross-sectional view cut along D-D in FIG. 1 according to some embodiments.

FIG. 7 is a cross-sectional view cut along E-E in FIG. 1 according to some embodiments.

FIG. 8 is an enlarged view of a P portion of FIG. 6 according to some embodiments.

FIGS. 9 to 14 are diagrams schematically showing a grain shape of a gate electrode pattern in FIG. 8 on a cross-sectional cut in a direction in which a bit-line extends, respectively according to some embodiments.

FIGS. 15 to 19 are diagrams schematically showing a grain shape of the gate electrode pattern in FIG. 8 on a cross-sectional cut in a direction in which a word-line extends, respectively according to some embodiments.

FIGS. 20 to 23 are diagrams for illustrating a semiconductor memory device according to some embodiments.

FIGS. 24 to 31 are diagrams of intermediate structures corresponding to intermediate steps of a method for manufacturing a semiconductor memory device according to some embodiments.

### DETAILED DESCRIPTIONS

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

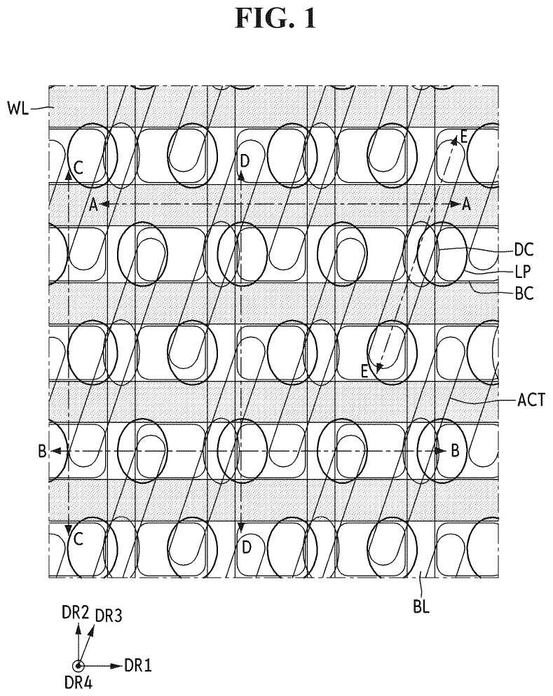

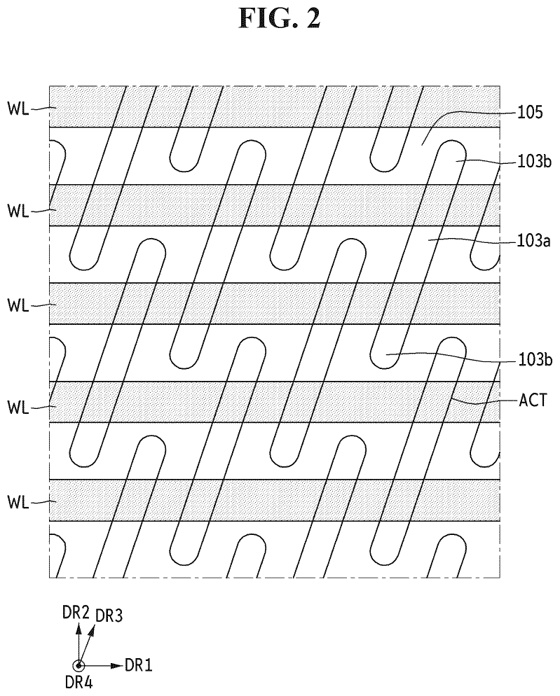

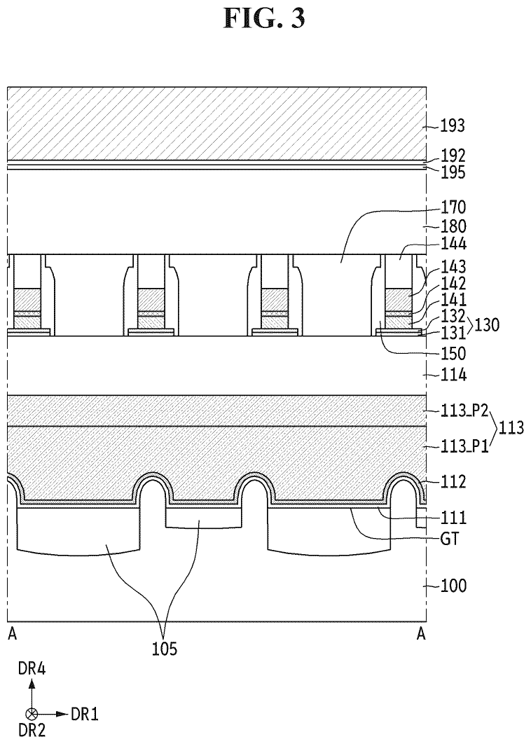

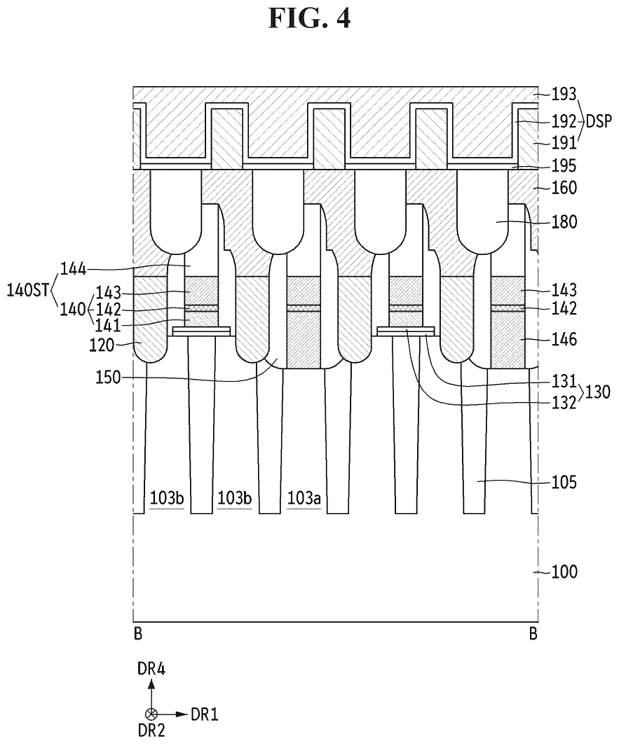

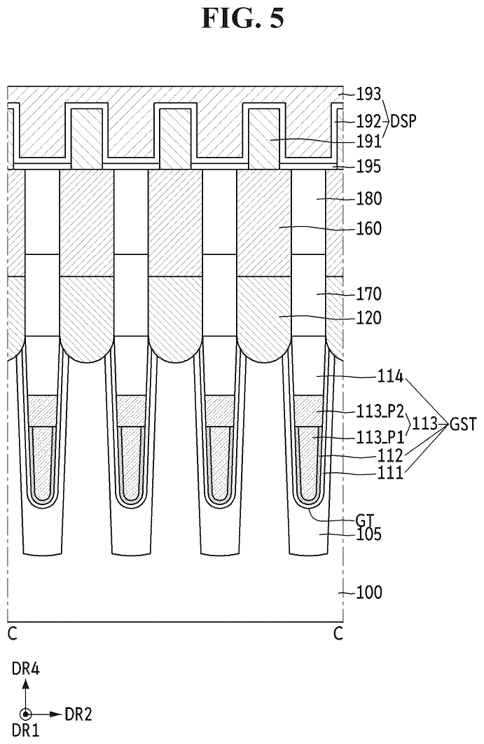

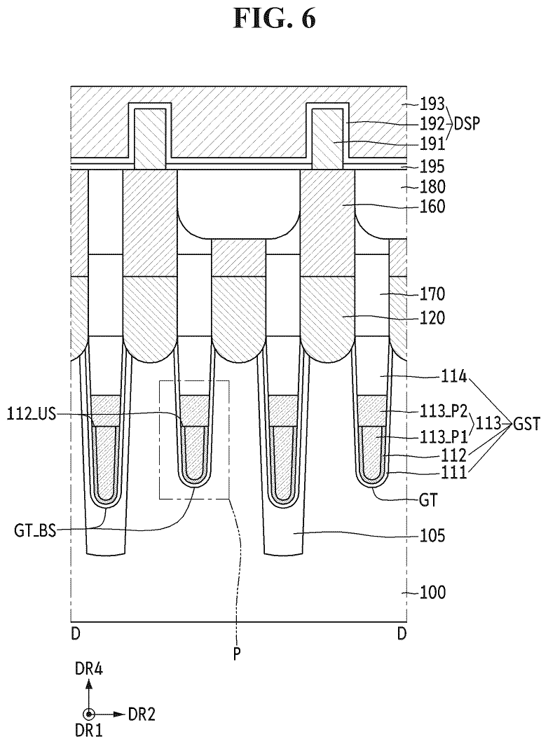

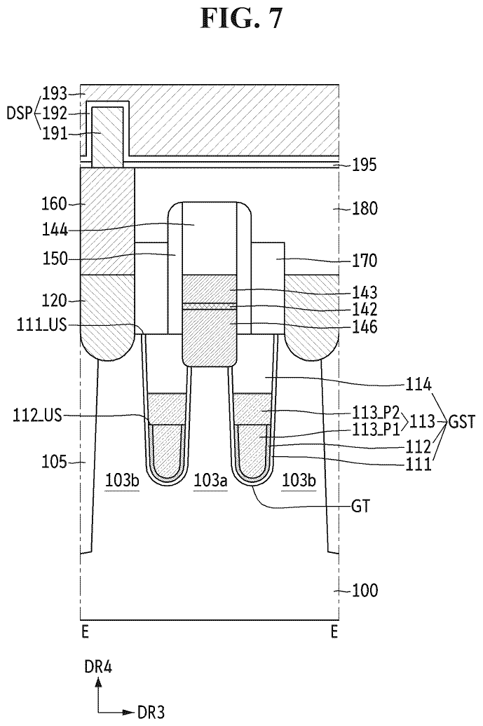

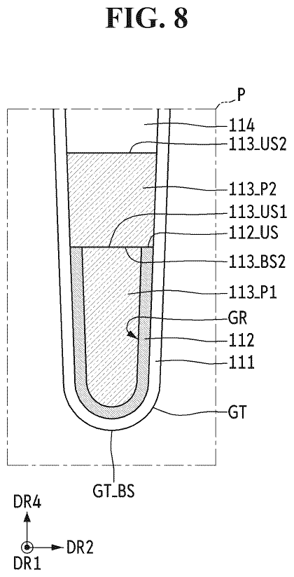

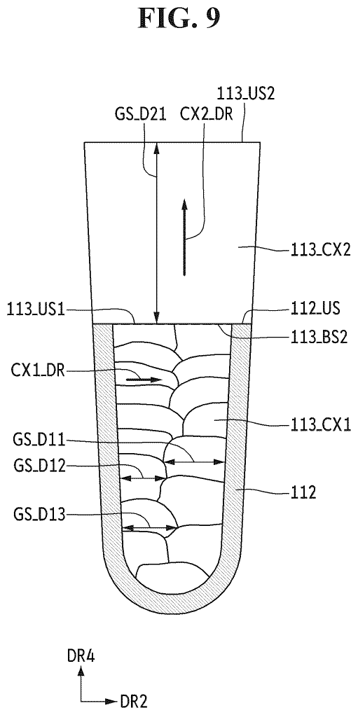

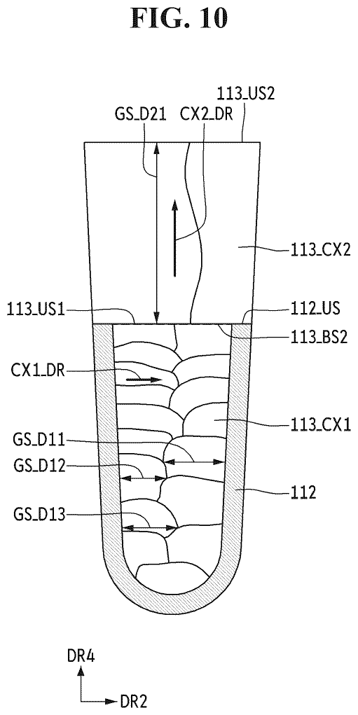

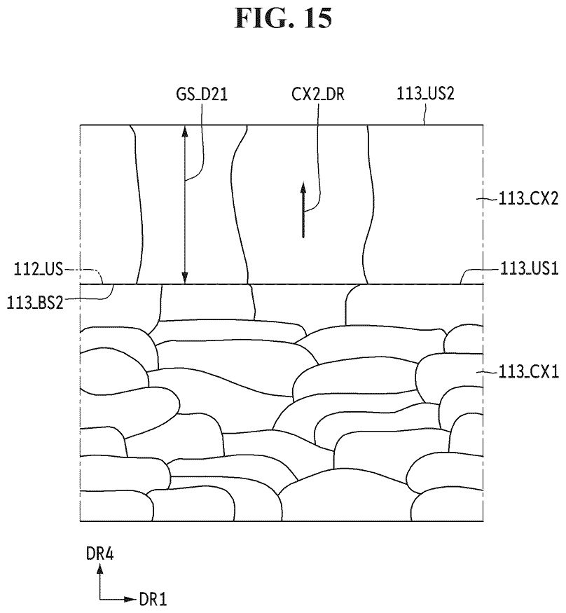

FIG. 1 is a schematic layout diagram of a semiconductor memory device according to some embodiments. FIG. 2 is a layout diagram showing a word-line and an active area of FIG. 1. FIG. 3 is a cross-sectional view cut along A-A in FIG. 1. FIG. 4 is a cross-sectional view cut along B-B in FIG. 1. FIG. 5 is a cross-sectional view cut along C-C in FIG. 1. FIG. 6 is a cross-sectional view cut along D-D in FIG. 1. FIG. 7 is a cross-sectional view cut along E-E in FIG. 1. FIG. 8 is an enlarged view of a P portion of FIG. 6. FIGS. 9 to 14 are diagrams schematically showing a grain shape of a gate electrode pattern in FIG. 8 on a cross-sectional cut in a direction in which a bit-line extends, respectively. FIGS. 15 to 19 are diagrams schematically showing a grain shape of the gate electrode pattern in FIG. 8 on a cross-sectional cut in a direction in which a word-line extends, respectively.

A semiconductor memory device according to embodiments may include memory cells, each including a buried channel array transistor (BCAT).

Referring to FIG. 1 and FIG. 2, the semiconductor memory device according to some embodiments may include a plurality of active areas ACT.

The active area ACT may be defined by an element isolation film 105 formed in a substrate (100 of FIG. 3). As a design rule of a semiconductor memory device decreases, the active area ACT may extend in a bar shape of a diagonal line or an oblique line. For example, the active area ACT may extend in a third direction DR3.

A plurality of gate electrodes may extend in a first direction DR1 and across the active area ACT. The plurality of gate electrodes may extend in parallel. The plurality of gate electrodes may be, for example, a plurality of word-lines WL. The word-line WL may be arranged so as to be spaced from each other at an equal spacing. A width of the word-line WL or the spacing between the word-lines WL may be determined based on the design rule. A conductive line included in the gate structure GST may be a word-line WL.

A plurality of bit-lines BL extending in a second direction DR2 and orthogonal to the word-line WL may be disposed on the word-line WL. The plurality of bit-lines BL may extend in parallel. The bit-lines BL may be arranged so as to be spaced from each other at an equal spacing. A width of the bit-line BL or the spacing between the bit-lines BL may be determined based on the design rule.

Each of the be divided into three portions by two word-lines WL extending in the first direction DR1. The active area ACT may include a first portion 103a and a second portion 103b defined on each of both opposite sides of the first portion 103a. The first portion 103a of the active area ACT may be located in a middle portion of the active area ACT, and each second portion 103b of the active area ACT may be located in each of both opposite ends of the active area ACT. For example, the first portion 103a of the active area ACT may be an area connected to the bit-line BL, and the second portion 103b of the active area ACT may be an area connected to a data storage pattern (DSP in FIG. 4). In this regard, a common drain area may be located in the first portion 103a of the active area ACT, and a source area may be located in the second portion 103b of the active area ACT. The word-line WL extending across an area between the first portion 103a of the active area ACT and the second portion 103b of the active area ACT, the first portion 103a of the active area ACT and the second portion 103b of the active area ACT may constitute a transistor.

A fourth direction DR4 may be orthogonal to the first direction DR1, the second direction DR2, and the third direction DR3. The fourth direction DR4 may be a thickness direction of the substrate 100.

The semiconductor memory device according to some embodiments may include various contact arrays formed on the active area ACT. The various contact arrangements may include, for example, a direct contact (DC), a buried contact (BC), and a landing pad (LP).

In this regard, the direct contact DC may indicate a contact electrically connecting the active area ACT to the bit-line BL. The buried contact BC may indicate a contact that connects the active area ACT to a lower electrode (191 of FIG. 4) of a capacitor. Due to a layout structure, a contact area between the buried contact BC and the active area ACT may be small. Accordingly, in order to increase the contact area between the buried contact BC and the active area ACT and a contact area between the buried contact BC and the lower electrode (191 of FIG. 4) of the capacitor, a conductive landing pad LP may be introduced.

The landing pad LP may be disposed between the active area ACT and the buried contact BC and between the buried contact BC and the lower electrode (191 of FIG. 4) of the capacitor. In the semiconductor memory device according to some embodiments, the landing pad LP may be disposed between the buried contact BC and the lower electrode (191 of FIG. 4) of the capacitor. The contact area may increase due to the introduction of the landing pad LP, such that a contact resistance between the active area ACT and the lower electrode (191 of FIG. 4) of the capacitor may be reduced.

The direct contact DC may be disposed on a central portion of the active area ACT. The direct contact DC may be connected to the first portion 103a of the active area ACT. The buried contact BC may be disposed on each of both opposite ends of the active area ACT. The buried contact BC may be connected to the second portion 103b of the active area ACT.

As the buried contact BC is disposed at each of both opposite ends of the active area ACT, the landing pad LP may be disposed adjacent to each of both opposite ends of the active area ACT so as to partially overlap the buried contact BC. In this regard, the buried contact BC may be formed to overlap a portion of each of the active area ACT and the element isolation film 105 disposed between adjacent word-lines WL and between adjacent bit-lines BL.

The word-line WL may be formed as a structure buried in the substrate 100. The word-line WL may extend across a portion of the active area ACT and disposed between the direct contacts DC or the buried contacts BC. As shown, two word-lines WL may intersect one active area ACT. As the active area ACT extends along the third direction DR3, the word-line WL may define an angle less than 90 degrees relative to the active area ACT.

The direct contacts DC may be arranged symmetrically. The buried contacts BC may be arranged symmetrically. Thus, the direct contacts DC may be arranged in a straight line along each of the first direction DR1 and the second direction DR2. The buried contacts BC may be arranged in a straight line along each of the first direction DR1 and the second direction DR2.

In one example, unlike the direct contact DC and the buried contact BC, the landing pads LP may be arranged in a zigzag pattern along the second direction DR2 in which the bit-line BL extends. Further, the landing pads LP may respectively overlap the same side faces of the bit-lines BL arranged in the first direction DR1 in which the word-line WL extends.

For example, the landing pads LP of a first line may respectively overlap left side faces of corresponding bit-lines BL, while the landing pads LP of a second line may respectively overlap right side faces of corresponding bit-lines BL.

Referring to FIG. 1 to FIG. 8, the semiconductor memory device according to some embodiments may include a plurality of gate trenches GT, a plurality of gate structures GST, a plurality of bit-line structures 140ST, a plurality of bit-line contacts 146, and the data storage pattern DSP.

The substrate 100 may be a silicon substrate or an SOI (silicon-on-insulator) substrate. Alternatively, the substrate 100 may include, but is not limited to, silicon germanium, SGOI (silicon germanium on insulator), indium antimonide, a lead telluride compound, indium arsenide, indium phosphide, gallium arsenide, or gallium antimonide.

The element isolation film 105 may be disposed in the substrate 100. The element isolation film 105 may have an STI (shallow trench isolation) structure having excellent element isolation ability. The element isolation film 105 may define the active area ACT in a memory cell area. As shown in FIG. 1 and FIG. 2, the active area ACT defined by the element isolation film 105 may have an elongate island shape including a short side and a long side. The active area ACT may extend diagonally so as to define an angle less than 90 degrees with respect to the word-line WL formed in the element isolation film 105. Further, the active area ACT may extend diagonally so as to define an angle less than 90 degrees with respect to the bit-line BL disposed on the element isolation film 105.

The element isolation film 105 may include, for example, at least one of a silicon oxide film, a silicon nitride film, and a silicon oxynitride film. However, embodiments are not limited thereto. In FIGS. 3 to 7, the element isolation film 105 is shown as a single insulating film. However, this is only for convenience of illustration, and embodiments are not limited thereto. Depending on a distance between adjacent active areas ACT, the element isolation film 105 may be one insulating film or a stack of a plurality of insulating films.

In FIGS. 3 to 7, it is shown that an upper surface of the element isolation film 105 and an upper surface of the substrate 100 are coplanar with each other. However, this is only for convenience of illustration, and embodiments are not limited thereto.

The plurality of gate trenches GT may be disposed within the substrate 100 and the element isolation film 105. The gate trench GT may extend across the element isolation film 105 and the active area ACT defined by the element isolation film 105. The gate trench GT may include a sidewall and a bottom surface GT_BS.

As shown in FIG. 3 and FIG. 6, the gate trench GT may be relatively deep within the element isolation film 105 and may be relatively shallow within the active area ACT. A bottom surface of the word-line WL may be curved. More specifically, in the fourth direction DR4 and based on a bottom of the element isolation film 105, a vertical level of the bottom surface GT_BS of the gate trench GT formed within the element isolation film 105 may be lower than a vertical level of the bottom surface GT_BS of the gate trench GT formed within the active area ACT. In this regard, the depth of the gate trench GT in the element isolation film 105 may be greater than the depth of the gate trench GT in the active area ACT.

The plurality of gate structures GST may be respectively disposed within the plurality of gate trenches GT. The gate structure GST may include a gate insulating film 111, a gate conductive film 112, a gate electrode pattern 113, and a gate capping film 114. In this regard, the gate conductive film 112 and the gate electrode pattern 113 may correspond to the word-line WL. For example, the gate conductive film 112 and the gate electrode pattern 113 may be the word-line WL in FIG. 1.

The gate insulating film 111 may extend in the first direction DR1 and along the sidewall and the bottom surface GT_BS of the gate trench GT. The gate insulating film 111 may extend along a profile of at least a portion of the gate trench GT.

The gate insulating film 111 may include inner and outer surfaces opposite to each other. The outer surface of the gate insulating film 111 may face the substrate 100. The gate insulating film 111 may include an upper surface 111_US. The upper surface 111_US of the gate insulating film 111 may be a surface connecting the inner surface of the gate insulating film 111 and the outer surface of the gate insulating film 111.

For example, the gate insulating film 111 may include at least one of silicon oxide, silicon nitride, silicon oxynitride, or a high dielectric constant material having a higher dielectric constant than that of silicon oxide. The high dielectric constant material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or combinations thereof. However, embodiments are not limited thereto.

The gate conductive film 112 may be disposed on the gate insulating film 111. The gate conductive film 112 may be disposed on the inner surface of the gate insulating film 111. The gate conductive film 112 may extend in the first direction DR1. The gate conductive film 112 may extend along at least a portion of a profile of the gate insulating film 111. The inner surface of the gate insulating film 111 may include a first portion in contact with the gate conductive film 112 and a second portion not in contact with the gate conductive film 112.

The gate conductive film 112 may include inner and outer surfaces opposite to each other. The outer surface of the gate conductive film 112 may be in contact with the gate insulating film 111. More specifically, the outer surface of the gate conductive film 112 may contact the first portion of the inner surface of the gate insulating film 111. The gate conductive film 112 may include an upper surface 112_US. The upper surface 112_US of the gate conductive film 112 may be a surface connecting the inner surface and the outer surface of the gate conductive film 112.

In the fourth direction DR4, based on the bottom surface GT_BS of the gate trench GT, a vertical level of the upper surface 112_US of the gate conductive film 112 may be lower than a vertical level of the upper surface 111_US of the gate insulating film 111.

The gate conductive film 112 may define a gate recess GR. The gate recess GR may indicate a space defined by the inner surface of the gate conductive film 112. The gate conductive film 112 is shown as having a U-shape. However, embodiments are not limited thereto. For example, the gate conductive film 112 may have a V-shape.

The gate conductive film 112 may include, for example, one of titanium nitride (TiN), molybdenum nitride (MoN), tungsten nitride (WN), and tantalum nitride (TaN). However, embodiments are not limited thereto.

The gate electrode pattern 113 may be disposed on the gate insulating film 111 and the gate conductive film 112. The gate electrode pattern 113 may be disposed on the second portion of the inner surface of the gate insulating film 111, the upper surface 112_US of the gate conductive film 112, and the inner surface of the gate conductive film 112. The gate electrode pattern 113 may extend in the first direction DR1. The gate electrode pattern 113 may fill the gate recess GR. The gate electrode pattern 113 may contact the second portion of the inner surface of the gate insulating film 111, the upper surface 112_US of the gate conductive film 112, and the inner surface of the gate conductive film 112.

The gate electrode pattern 113 may include a first portion 113_P1 and a second portion 113_P2. The first portion 113_P1 of the gate electrode pattern 113 may be disposed on the gate conductive film 112. The first portion 113_P1 of the gate electrode pattern 113 may contact the inner surface of the gate conductive film 112. The first portion 113_P1 of gate electrode pattern 113 may fill the gate recess GR.

The second portion 113_P2 of the gate electrode pattern 113 may be disposed on the gate insulating film 111, the gate conductive film 112, and the first portion 113_P1 of the gate electrode pattern 113. The second portion 113_P2 of the gate electrode pattern 113 may contact the second portion of the inner surface of the gate insulating film 111, the upper surface 112_US of the gate conductive film 112, and the first portion 113_P1 of the gate electrode pattern 113.

The first portion 113_P1 of the gate electrode pattern 113 may include an upper surface 113_US1. The upper surface 113_US1 of the first portion 113_P1 of the gate electrode pattern 113 may contact the second portion 113_P2 of the gate electrode pattern 113.

The second portion 113_P2 of the gate electrode pattern 113 may include an upper surface 113_US2 and a bottom surface 113_BS2 opposite to each other in the fourth direction DR4. The bottom surface 113_BS2 of the second portion 113_P2 of the gate electrode pattern 113 may face the first portion 113_P1 of the gate electrode pattern 113 and the gate conductive film 112. The bottom surface 113_BS2 of the second portion 113_P2 of the gate electrode pattern 113 may contact the first portion 113_P1 of the gate electrode pattern 113 and the gate conductive film 112.

Referring to FIGS. 8 to 14, the first portion 113_P1 of the gate electrode pattern 113 may include a plurality of first conductive material crystals 113_CX1. The second portion 113_P2 of the gate electrode pattern 113 may include a plurality of second conductive material crystals 113_CX2. Each of the first conductive material crystal 113_CX1 may be a crystal grain of a first conductive material. Each of the second conductive material crystal 113_CX2 may be a crystal grain of a second conductive material. At least some of the plurality of first conductive material crystals 113_CX1 may contact at least some of the plurality of second conductive material crystals 113_CX2. In a cross-sectional view of the gate electrode pattern 113 cut in a direction in which the bit-line BL extends, the second conductive material crystal 113_CX2 may be a single conductive material crystal.

In the cross-sectional view of the gate electrode pattern 113 cut in the second direction DR2, the plurality of first conductive material crystals 113_CX1 may be stacked in the fourth direction DR4. The plurality of first conductive material crystals 113_CX1 may be stacked in a direction perpendicular to the upper surface of the substrate 100. The plurality of second conductive material crystals 113_CX2 may be arranged in the second direction DR2. The plurality of second conductive material crystals 113_CX2 may be arranged in a direction in which each bit-line BL extends. The first portion 113_P1 of the gate electrode pattern 113 may include the plurality of first conductive material crystals 113_CX1 stacked in the fourth direction DR4. The second portion 113_P2 of the gate electrode pattern 113 may include the plurality of second conductive material crystals 113_CX2 arranged in the second direction DR2.

In a cross-sectional view of the gate electrode pattern 113 cut in the second direction DR2, a crystal orientation CX1_DR of each of the first conductive material crystals 113_CX1 may be the second direction DR2. The crystal orientation CX1_DR of each of the first conductive material crystal 113_CX1 may be a direction in which the bit-line BL extends. The first portion 113_P1 of the gate electrode pattern 113 may include the plurality of first conductive material crystals 113_CX1 in which the crystal orientation CX1_DR is the second direction DR2. A crystal orientation CX2_DR of each of the second conductive material crystal 113_CX2 may be the fourth direction DR4. The crystal orientation CX2_DR of each of the second conductive material crystals 113_CX2 may be a direction perpendicular to the upper surface of the substrate 100. The second portion 113_P2 of the gate electrode pattern 113 may include the plurality of second conductive material crystals 113_CX2 in which the crystal orientation CX2_DR is the fourth direction DR4. In this regard, ‘crystal orientation’ may indicate a direction closer to a direction in which each conductive material crystal has grown among the direction perpendicular to the upper surface of the substrate 100 and the direction in which the bit-line BL extends.

For example, each of the first conductive material crystal 113_CX1 and the second conductive material crystal 113_CX2 may be formed in a bottom-up growth method. Through analysis of the grain of the gate electrode pattern 113, a person skilled in the art may appreciate the direction in which each of the first conductive material crystal 113_CX1 and the second conductive material crystal 113_CX2 has grown.

Each of the first conductive material crystal 113_CX1 and the second conductive material crystal 113_CX2 may have a crystal grain size. The first conductive material crystal 113_CX1 may have crystal grain sizes GS_D11, GS_D12, and GS_D13 in the second direction DR2. The second conductive material crystal 113_CX2 may have crystal grain sizes GS_D21, GS_D22, and GS_D23 in the fourth direction DR4.

The first conductive material crystal 113_CX1 included in the first portion 113_P1 of the gate electrode pattern 113 may have a first average crystal grain size in the second direction DR2. The first average crystal grain size of the first conductive material crystal 113_CX1 may be an average value of the crystal grain sizes GS_D11, GS_D12, and GS_D13 in the second direction DR2. The second conductive material crystal 113_CX2 included in the second portion 113_P2 of the gate electrode pattern 113 may have a second average crystal grain size in the fourth direction DR4. The second average crystal grain size of the second conductive material crystal 113_CX2 may be an average value of the crystal grain sizes GS_D21, GS_D22, and GS_D23 in the fourth direction DR4.

The second average crystal grain size may be greater than the first average crystal grain size. For example, the second average crystal grain size may be greater than or equal to three times of the first average crystal grain size.

The upper surface 113_US1 of the first portion 113_P1 of the gate electrode pattern 113 may be defined by the plurality of first conductive material crystals 113_CX1. The upper surface 113_US1 of the first portion 113_P1 of the gate electrode pattern 113 may be defined by a collection of the plurality of first conductive material crystals 113_CX1. The first conductive material crystal 113_CX1 which defines the upper surface 113_US1 of the first portion 113_P1 of the gate electrode pattern 113 may be in contact with the second conductive material crystal 113_CX2.

The upper surface 113_US2 and the bottom surface 113_BS2 of the second portion 113_P2 of the gate electrode pattern 113 may be defined by the plurality of second conductive material crystals 113_CX2. The upper surface 113_US2 and the bottom surface 113_BS2 of the second portion 113_P2 of the gate electrode pattern 113 may be defined by a collection of the plurality of second conductive material crystals 113_CX2.

At least one of the plurality of second conductive material crystals 113_CX2 may extend from the upper surface 113_US2 of the second portion 113_P2 of the gate electrode pattern 113 to the bottom surface 113_BS2 of the second portion 113_P2 of the gate electrode pattern 113. In this regard, a height in the fourth direction DR4 of at least one of the plurality of second conductive material crystals 113_CX2 may be equal to a height in the fourth direction DR4 of the second portion 113_P2 of the gate electrode pattern 113. The height in the fourth direction DR4 each of the plurality of second conductive material crystals 113_CX2 may be the crystal grain size GS_D21, GS_D22, or GS_D23 in the fourth direction DR4.

Each of the first portion 113_P1 of the gate electrode pattern 113 and the second portion 113_P2 of the gate electrode pattern 113 may include a conductive material. Each of the first portion 113_P1 of the gate electrode pattern 113 and the second portion 113_P2 of the gate electrode pattern 113 may include a conductive material capable of selective growth. Each of the first portion 113_P1 of the gate electrode pattern 113 and the second portion 113_P2 of the gate electrode pattern 113 may include one of cobalt (Co), tungsten (W), and molybdenum (Mo). However, embodiments are not limited thereto.

The first portion 113_P1 of the gate electrode pattern 113 and the second portion 113_P2 of the gate electrode pattern 113 may include the same conductive material. That is, the first conductive crystal material 113_CX1 included in the first portion 113_P1 of the gate electrode pattern 113 and the second conductive crystal material 113_CX2 included in the second portion 113_P2 of the gate electrode pattern 113 may include the same conductive material. The same conductive material may include, for example, one of cobalt (Co), tungsten (W), and molybdenum (Mo). However, embodiments are not limited thereto. The first portion 113_P1 of gate electrode pattern 113 and the second portion 113_P2 of gate electrode pattern 113 include the same conductive material, whereas a boundary between the first portion 113_P1 of gate electrode pattern 113 and the second portion 113_P2 of gate electrode pattern 113 may be clearly defined. Because the crystal orientation CX1_DR of the first conductive material crystal 113_CX1 is distinct from the crystal orientation CX2_DR of the second conductive material crystal 113_CX2, the boundary between the first portion 113_P1 of the gate electrode pattern 113 and the second portion 113_P2 of the gate electrode pattern 113 may be clearly defined.

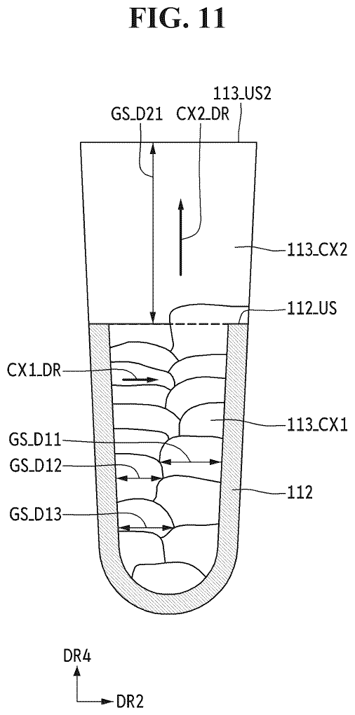

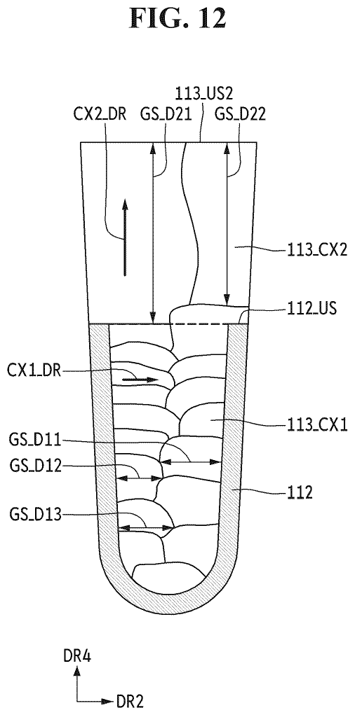

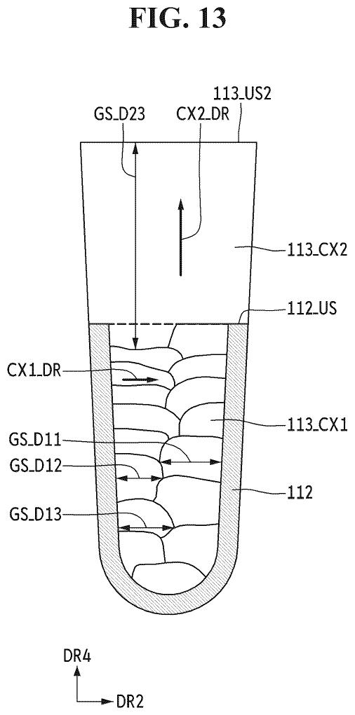

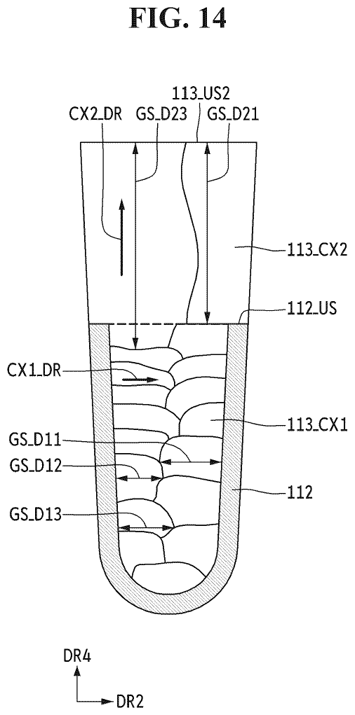

The upper surface 113_US1 of the first portion 113_P1 of the gate electrode pattern 113 may be the boundary between the first portion 113_P1 of the gate electrode pattern 113 and the second portion 113_P2 of the gate electrode pattern 113. In FIG. 8 and FIG. 9, the upper surface 113_US1 of the first portion 113_P1 of the gate electrode pattern 113 is shown to be coplanar with the upper surface 112_US of the gate conductive film 112. However, this is only for convenience of illustration, and embodiments are not limited thereto. Referring to FIG. 11 and FIG. 12, in the cross-sectional view of the gate electrode pattern 113 cut in the second direction DR2, and based on the bottom surface GT_BS of the gate trench GT, a vertical level of a portion of the boundary between the first portion 113_P1 of the gate electrode pattern 113 and the second portion 113_P2 of the gate electrode pattern 113 may be higher than a vertical level of the upper surface 112_US of the gate conductive film 112. Referring to FIG. 13 and FIG. 14, based on the bottom surface GT_BS of the gate trench GT, a vertical level of a portion of the boundary between the first portion 113_P1 of the gate electrode pattern 113 and the second portion 113_P2 of the gate electrode pattern 113 may be lower than the vertical level of the upper surface 112_US of the gate conductive film 112.

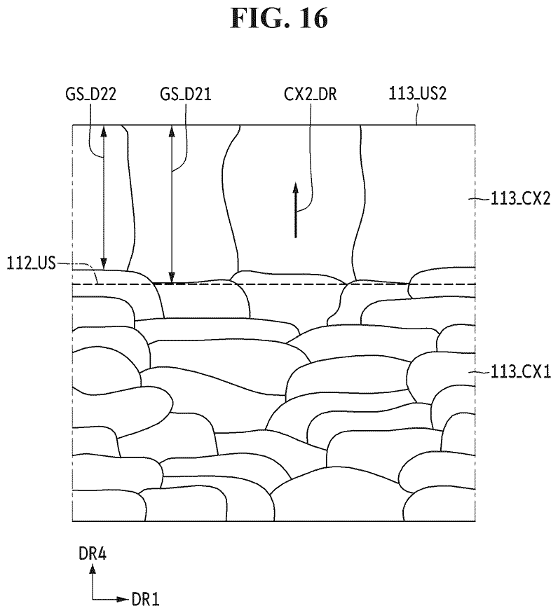

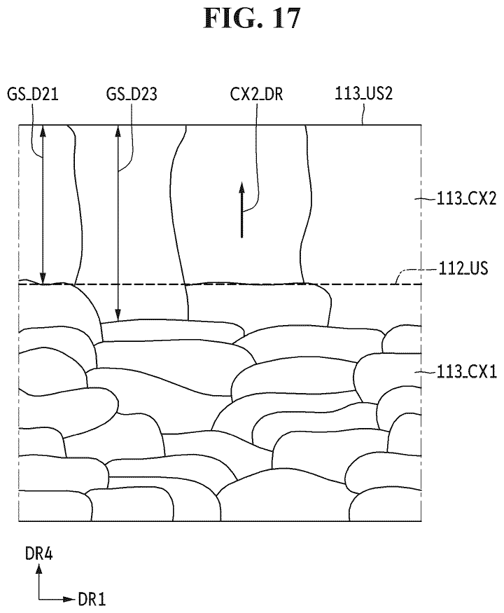

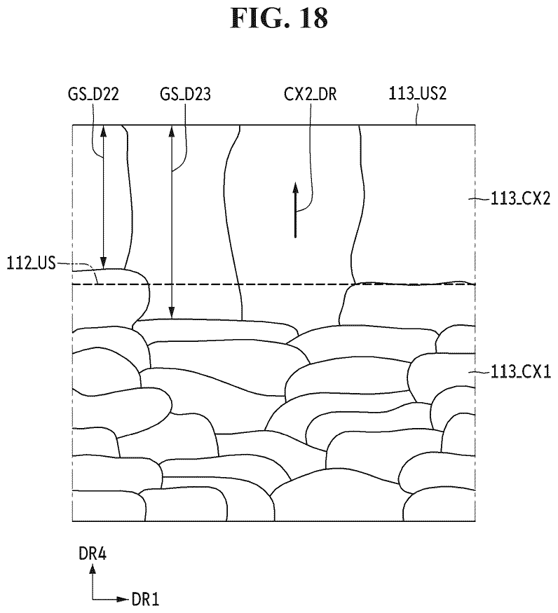

In FIG. 3 and FIG. 15, the boundary between the first portion 113_P1 of the gate electrode pattern 113 and the second portion 113_P2 of the gate electrode pattern 113 is shown as extending in parallel with the first direction DR1. This is only for convenience of illustration, and embodiments are not limited thereto. In FIG. 16, a cross-sectional view of the gate electrode pattern cut in the direction where the word-line WL extends, a vertical level of a portion of the boundary between the first portion 113_P1 of the gate electrode pattern 113 and the second portion 113_P2 of the gate electrode pattern 113 may be higher than a vertical level of the upper surface 112_US of the gate conductive film 112. Referring to FIG. 17, a vertical level of a portion of the boundary between the first portion 113_P1 of the gate electrode pattern 113 and the second portion 113_P2 of the gate electrode pattern 113 may be lower than a vertical level of the upper surface 112_US of the gate conductive film 112. Referring to FIG. 18, a vertical level of the portion of the boundary between the first portion 113_P1 of the gate electrode pattern 113 and the second portion 113_P2 of the gate electrode pattern 113 may be higher than a vertical level of the upper surface 112_US of the gate conductive film 112, while a vertical level of another portion of the boundary between the first portion 113_P1 of the gate electrode pattern 113 and the second portion 113_P2 of the gate electrode pattern 113 may be lower than a vertical level of the upper surface 112_US of the gate conductive film 112.

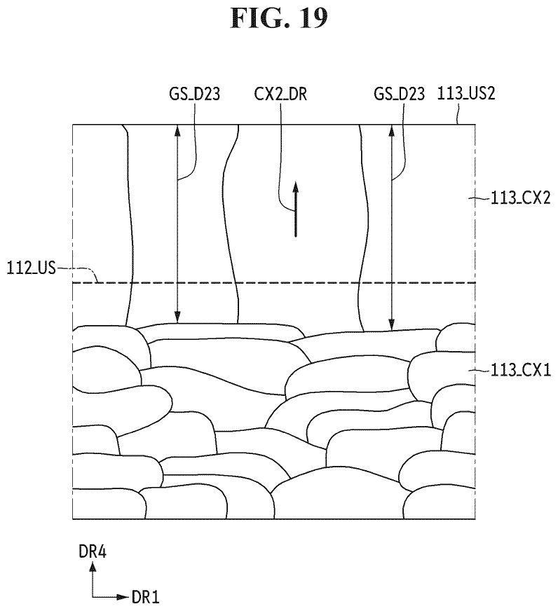

In FIG. 3 and FIGS. 15 to 18, at least a portion of the boundary between the first portion 113_P1 of the gate electrode pattern 113 and the second portion 113_P2 of the gate electrode pattern 113 is shown to be coplanar with the upper surface 112_US of the gate conductive film 112. However, embodiments are not limited thereto. Referring to FIG. 19, a vertical level of the boundary between the first portion 113_P1 of the gate electrode pattern 113 and the second portion 113_P2 of the gate electrode pattern 113 may be lower than a vertical level of the upper surface 112_US of the gate conductive film 112.

The second portion 113_P2 of the gate electrode pattern 113 may include the plurality of second conductive material crystals 113_CX2 having the crystal orientation CX2_DR of the fourth direction DR4. Thus, the crystal grain sizes GS_D21 GS_D22 and GS_D23 of the second conductive material crystal 113_CX2 included in the second portion 113_P2 of the gate electrode pattern 113 increase. As the crystal grain size GS_D21 GS_D22 and GS_D23 of the second conductive material crystal 113_CX2 increases, the number of grain boundaries within the second portion 113_P2 of the gate electrode pattern 113 may decrease. Electrons flowing through the second portion 113_P2 of the gate electrode pattern 113 may be scattered at the grain boundaries between the second conductive material crystals 113_CX2. When the number of electrons flowing through the second portion 113_P2 of the gate electrode pattern 113 are scattered increases, the resistance of the second portion 113_P2 of the gate electrode pattern 113 may increase. However, because the second portion 113_P2 of the gate electrode pattern 113 includes the plurality of second conductive material crystals 113_CX2 having the crystal orientation CX2_DR of the fourth direction DR4, the number of electrons flowing through the second portion 113_P2 of the gate electrode pattern 113 are scattered may decrease. That is, the resistance of the second portion 113_P2 of the gate electrode pattern 113 may be reduced. Thus, the performance and reliability of the semiconductor memory device according to some embodiments may be improved.

The gate capping film 114 may be disposed on the gate conductive film 112 and the gate electrode pattern 113. The gate capping film 114 may fill a portion of the gate trench GT remaining after the gate conductive film 112 and the gate electrode pattern 113 have been formed therein.

For example, the gate capping film 114 may include at least one of silicon nitride (SiN), silicon oxynitride (SiON), silicon oxide (SiO₂), silicon carbonitride (SiCN), silicon oxycarbonitride (SiOCN), and combinations thereof.

The bit-line structure 140ST may include a conductive line 140, a bit-line capping film 144, and a bit-line spacer 150.

The conductive line 140 may be disposed on the substrate 100 and the element isolation film 105 in which the gate structure GST has been formed. The conductive line 140 may intersect the active area ACT defined by the element isolation film 105 and the element isolation film 105. The conductive line 140 may be disposed to intersect the gate structure GST. In this regard, the conductive line 140 may correspond to the bit-line BL. For example, the conductive line 140 may be the bit-line BL in FIG. 1.

For example, the conductive line 140 may include at least one of a semiconductor material doped with impurities, a conductive silicide compound, a conductive metal nitride, a two-dimensional (2D) material, a metal, and a metal alloy. In a semiconductor memory device according to some embodiments, the two-dimensional material may be a metallic material and/or a semiconductor material. The two-dimensional material (2D material) may include a two-dimensional allotrope or a two-dimensional compound. For example, the 2D material may include at least one of graphene, molybdenum disulfide (MoS₂), molybdenum diselenide (MoSe₂), tungsten diselenide (WSe₂), and tungsten disulfide (WS₂). However, the present disclosure is not limited thereto. In this regard, the above-described two-dimensional materials are listed only by way of example. The two-dimensional material that may be included in the semiconductor memory device is not limited to the above-described materials.

According to embodiments, the conductive line 140 may be a single film or a double film. For example, the conductive line 140 may be a multi-film including a first conductive line 141, a second conductive line 142, and a third conductive line 143, as shown. As shown, the conductive line 140 may be a triple film. However, embodiments are not limited thereto. That is, the conductive line 140 may include either a single film or a stack of a plurality of conductive films made of conductive materials.

The bit-line capping film 144 may be disposed on the conductive line 140. The bit-line capping film 144 may extend along an upper surface of conductive line 140 and in the second direction DR2. For example, the bit-line capping film 144 may include at least one of a silicon nitride film, silicon oxynitride, silicon carbonitride, and silicon oxycarbonitride.

In a semiconductor memory device according to some embodiments, the bit-line capping film 144 may include a silicon nitride film. Although the bit-line capping film 144 is shown as a single film, embodiments are not limited thereto.

The bit-line contact 146 may be disposed between the conductive line 140 and the substrate 100. That is, the conductive line 140 may be disposed on the bit-line contact 146. For example, the bit-line contact 146 may be formed in an area in which the conductive line 140 and the middle portion of the active area ACT which has an elongate island shape intersect each other. The bit-line contact 146 may be disposed between the first portion 103a of the active area ACT and the conductive line 140. The bit-line contact 146 may electrically connect conductive line 140 and the substrate 100 to each other. In this regard, the bit-line contact 146 may correspond to the direct contact DC. For example, the bit-line contact 146 may include at least one of a semiconductor material doped with impurities, a conductive silicide compound, a conductive metal nitride, and a metal.

The bit-line insulating film 130 may be disposed on the substrate 100 and the element isolation film 105. More specifically, the bit-line insulating film 130 may be disposed on an upper surface of each of the substrate 100 and the element isolation film 105 in an area in which the bit-line contact 146 and the storage contact 120 are not formed. The bit-line insulating film 130 may be disposed between the substrate 100 and the conductive line 140 and between the element isolation film 105 and the conductive line 140.

Although the bit-line insulating film 130 may be a single film, the bit-line insulating film 130 may be a multi-film including a first cell insulating film 131 and a second cell insulating film 132 as shown. For example, the first cell insulating film 131 may include a silicon oxide film, and the second cell insulating film 132 may include a silicon nitride film. However, embodiments are not limited thereto. For example, the bit-line insulating film 130 may be a triple film including a silicon oxide film, a silicon nitride film, and a silicon oxide film. However, embodiments are not limited thereto.

The bit-line spacer 150 may be disposed on a sidewall of the conductive line 140 and a sidewall of the bit-line capping film 144. In a portion of the conductive line 140 in an area where the bit-line contact 146 is formed, the bit-line spacer 150 may be disposed on the substrate 100 and the element isolation film 105. The bit-line spacer 150 may be disposed on the sidewall of the conductive line 140, the sidewall of the bit-line capping film 144, and the sidewall of the bit-line contact 146. In the remaining portion of the conductive line 140 in an area where the bit-line contact 146 is not formed, the bit-line spacer 150 may be disposed on the bit-line insulating film 130. The bit-line spacer 150 may be disposed on the sidewall of the conductive line 140 and the sidewall of the bit-line capping film 144.

The bit-line spacer 150 is shown as a single film. However, this is only for convenience of illustration, and embodiments are not limited thereto. That is, in another example, the bit-line spacer 150 may have a multi-film structure. The bit-line spacer 150 may include, for example, a silicon oxide film, a silicon nitride film, a silicon oxynitride film (SiON), a silicon oxycarbonitride film (SiOCN), air, and a combination thereof. However, embodiments are not limited thereto. In one example, the bit-line spacer 150 may be composed of a double film including a silicon oxide film and a silicon nitride film.

A fence pattern 170 may be disposed on the substrate 100 and the element isolation film 105. The fence pattern 170 may be disposed to overlap the gate structure GST formed within the substrate 100 and the element isolation film 105.

The fence pattern 170 may be disposed between the bit-line structures 140ST extending in the second direction DR2. For example, the fence pattern 170 may include at least one of silicon oxide, silicon nitride, silicon oxynitride, and combinations thereof.

The storage contact 120 may be disposed between conductive lines 140 adjacent to each other in the first direction DR1. The storage contacts 120 may be respectively disposed on both opposite sides of the conductive line 140. More specifically, the storage contact 120 may be disposed between the bit-line structures 140ST. The storage contact 120 may be disposed between fence patterns 170 adjacent to each other in the second direction DR2.

The storage contact 120 may overlap a portion of the substrate 100 and a portion of the element isolation film 105 disposed between adjacent conductive lines 140. The storage contact 120 may be connected to the active area ACT. More specifically, the storage contact 120 may be connected to the second portion 103b of the active area ACT. In this regard, the storage contact 120 may correspond to the buried contact BC in FIG. 1.

For example, the storage contact 120 may include at least one of a semiconductor material doped with impurities, a conductive silicide compound, a conductive metal nitride, and a metal.

A storage pad 160 may be disposed on the storage contact 120. The storage pad 160 may be electrically connected to the storage contact 120. The storage pad 160 may be connected to the second portion 103b of the active area ACT. In this regard, the storage pad 160 may correspond to the landing pad LP.

The storage pad 160 may overlap a portion of the upper surface of the bit-line structure 140ST. For example, the storage pad 160 may include at least one of conductive metal nitride, conductive metal carbide, metal, and metal alloy.

A pad isolation insulating film 180 may be disposed on the storage pad 160 and the bit-line structure 140ST. For example, the pad isolation insulating film 180 may be disposed on the bit-line capping film 144. The pad isolation insulating film 180 may define the storage pad 160 as each of a plurality of isolated areas. The pad isolation insulating film 180 may not cover an upper surface of the storage pad 160. For example, based on the upper surface of the substrate 100, the upper surface of the storage pad 160 may be coplanar with the upper surface of the pad isolation insulating film 180.

The pad isolation insulating film 180 may include an insulating material and may electrically isolate the plurality of storage pads 160 from each other. For example, the pad isolation insulating film 180 may include at least one of a silicon oxide film, a silicon nitride film, a silicon oxynitride film, a silicon oxycarbonitride film, and a silicon carbonitride film.

An etch stop film 195 may be disposed on the upper surface of the storage pad 160 and the upper surface of the pad isolation insulating film 180. For example, the etch stop film 165 may include at least one of silicon nitride (SiN), silicon carbonitride (SiCN), silicon oxycarbonitride (SiOCN), silicon oxycarbide (SiOC), and silicon boron nitride (SiBN).

The data storage pattern DSP may be disposed on the storage pad 160. The data storage pattern DSP is connected to the storage pad 160. A portion of the data storage pattern DSP may be disposed within the etch stop film 195.

The data storage pattern DSP may include, for example, a capacitor. However, embodiments are not limited thereto. The data storage pattern DSP may include a lower electrode 191, a capacitor dielectric film 192, and an upper electrode 193. For example, the upper electrode 193 may be a plate upper electrode having a plate shape.

The lower electrode 191 may be disposed on the storage pad 160. The lower electrode 191 may have a pillar shape.

The capacitor dielectric film 192 may be disposed on the lower electrode 191. The capacitor dielectric film 192 may be formed along a profile of the lower electrode 191. The upper electrode 193 may be disposed on the capacitor dielectric film 192. The upper electrode 193 may cover an outer sidewall of the lower electrode 191. The upper electrode 193 is shown as a single film. However, this is only for convenience of illustration, and embodiments are not limited thereto.

Each of the lower electrode 191 and the upper electrode 193 may include, for example, a doped semiconductor material, a conductive metal nitride such as titanium nitride, tantalum nitride, niobium nitride or tungsten nitride, etc., a metal such as ruthenium, iridium, titanium, or tantalum, etc., or a conductive metal oxide such as iridium oxide or niobium oxide, etc. However, embodiments are not limited thereto.

The capacitor dielectric film 192 may include, but is not limited to, one of, for example, silicon oxide, silicon nitride, silicon oxynitride, a high dielectric constant material, and combinations thereof. In a semiconductor memory device according to some embodiments, the capacitor dielectric film 192 may have a stack structure of a ferroelectric material film and a paraelectric material film.

Alternatively, the data storage pattern DSP may be a variable resistance pattern that may be switched to between two states having different resistance values, according to an electrical pulse applied to a memory element. For example, the data storage pattern DSP may include a phase-change material in which a crystal state changes depending on an amount of current, perovskite compounds, transition metal oxides, magnetic materials, ferromagnetic materials, or antiferromagnetic materials.

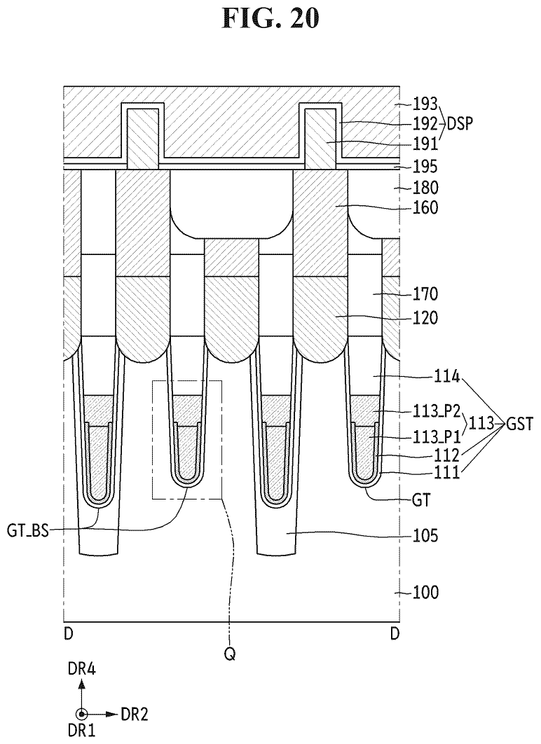

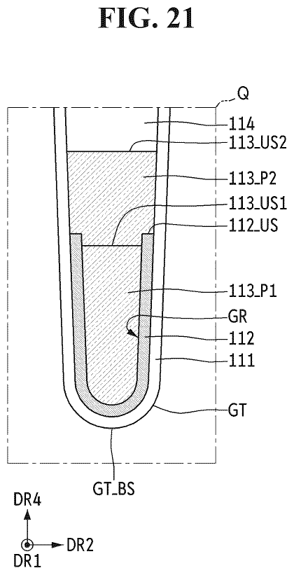

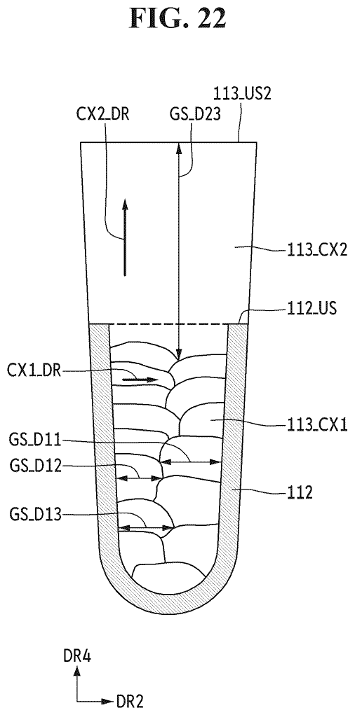

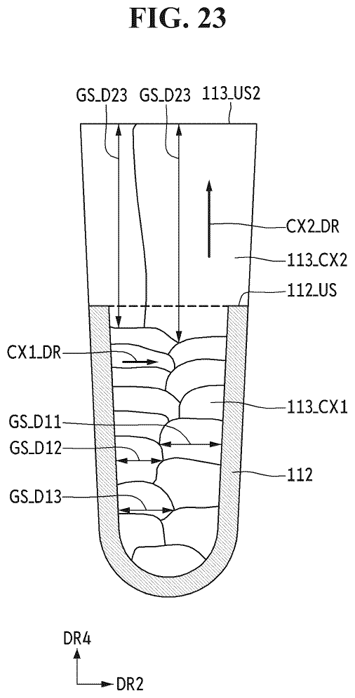

FIGS. 20 to 23 are diagrams for illustrating a semiconductor memory device according to some embodiments. For reference, FIG. 20 is a cross-sectional view cut along D-D in FIG. 1. FIG. 21 is an enlarged view of a Q portion of FIG. 20. FIGS. 22 and 23 are diagrams schematically showing a grain shape of a gate electrode pattern in FIG. 21 on cross-sectional cut in a direction in which the bit-line extends, respectively. For convenience of description, contents duplicate with the contents as described above using FIGS. 1 to 19 are briefly described or omitted.

Referring to FIGS. 20 to 23, in a semiconductor memory device according to some embodiments, the second portion 113_P2 of the gate electrode pattern 113 may be disposed on the inner surface of the gate conductive film 112. The inner surface of the gate conductive film 112 may contact the second portion 113_P2 of the gate electrode pattern 113.

The second portion 113_P2 of the gate electrode pattern 113 may contact the upper surface 112_US of the gate conductive film 112, the inner surface of the gate conductive film 112, and the first portion 113_P1 of the gate electrode pattern 113. The second portion 113_P2 of the gate electrode pattern 113 may fill a portion of the gate recess GR remaining after the first portion 113_P1 of the gate electrode pattern 113 have filled the same. The second portion 113_P2 of the gate electrode pattern 113 may have a shape that protrudes downwardly beyond the upper surface 112_US of the gate conductive film 112.

The second portion 113_P2 of the gate electrode pattern 113 includes the plurality of second conductive material crystals 113_CX2. The second conductive material crystal 113_CX2 may be a single conductive material crystal in a cross-sectional view as shown in FIG. 22.

In the second direction DR2, and based on the bottom surface GT_BS of the gate trench GT, a vertical level of the upper surface 113_US1 of the first portion 113_P1 of the gate electrode pattern 113 may be lower than a vertical level of the upper surface 112_US of the gate conductive film 112. The upper surface 113_US1 of the first portion 113_P1 of the gate electrode pattern 113 may be a boundary between the first portion 113_P1 of the gate electrode pattern 113 and the second portion 113_P2 of the gate electrode pattern 113. In the second direction DR2 and based on the bottom surface GT_BS of the gate trench GT, a vertical level of the boundary between the first portion 113_P1 of the gate electrode pattern 113 and the second portion 113_P2 of the gate electrode pattern 113 may be lower than a vertical level of the upper surface 112_US of the gate conductive film 112. In this regard, along the second direction DR2, a portion of the second portion 113_P2 of the gate electrode pattern 113 may be provided between the gate conductive film 112. In FIG. 20 and FIG. 21, the boundary between the first portion 113_P1 of the gate electrode pattern 113 and the second portion 113_P2 of the gate electrode pattern 113 is shown as being flat. However, this is only for convenience of illustration, and embodiments are not limited thereto. For example, as shown in FIG. 22 and FIG. 23, the first conductive material crystal 113_CX1 included in the first portion 113_P1 of the gate electrode pattern 113 may have irregularities. The upper surface 113_US1 of the first portion 113_P1 of the gate electrode pattern 113 defined by the collection of the first conductive material crystals 113_CX1 may have irregularities. That is, the boundary between the first portion 113_P1 of the gate electrode pattern 113 and the second portion 113_P2 of the gate electrode pattern 113 may have irregularities.

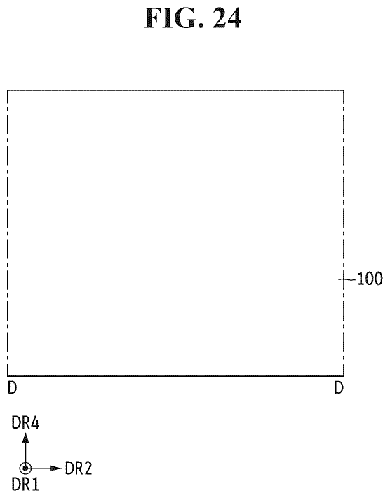

FIGS. 24 to 31 are diagrams of intermediate structures corresponding to intermediate steps of a method for manufacturing a semiconductor memory device according to some embodiments. For convenience of description, descriptions of the manufacturing method that duplicate with the contents described above using FIGS. 1 to 19 are briefly set forth or omitted. For reference, FIGS. 24 to 31 are cross-sectional views cut along D-D in FIG. 1.

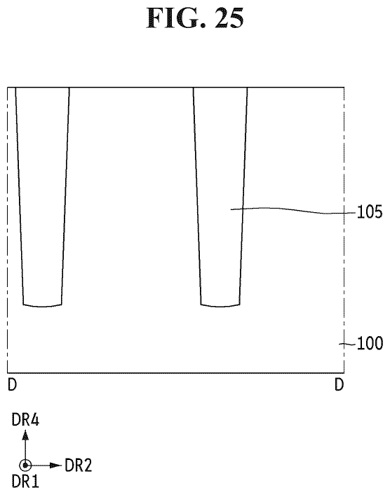

Referring to FIG. 2, FIG. 24, and FIG. 25, the substrate 100 may be provided. The element isolation film 105 may be formed within the substrate 100. The element isolation film 105 is shown as being formed as a single insulating film. However, this is only for convenience of illustration, and embodiments are not limited thereto. Depending on the distance between adjacent active areas ACT, the element isolation film 105 may be formed as a single insulating film or as a stack of a plurality of insulating films.

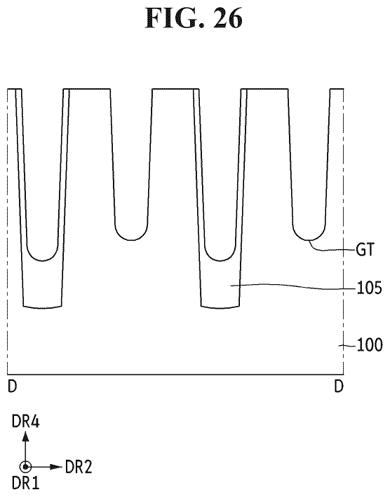

Referring to FIG. 26, the gate trench GT may be formed within the substrate 100 and the element isolation film 105. For example, after forming a mask pattern on the substrate 100, the substrate 100 may be etched using the mask pattern as an etch mask to form the gate trench GT. The gate trench GT may extend in the first direction DR1. The gate trench GT may extend across the element isolation film 105 and the active area ACT defined by the element isolation film 105.

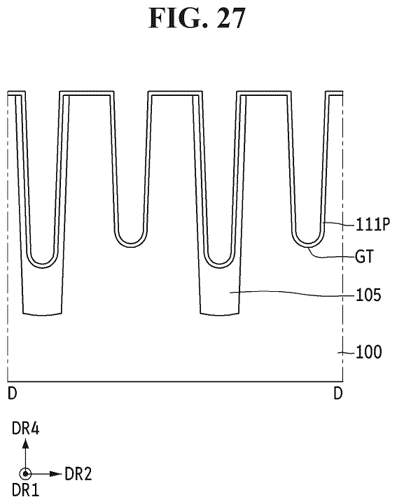

Referring to FIG. 27, a gate insulating pattern 111P may be formed on the substrate 100 and within the gate trench GT. The gate insulating pattern 111P may be formed using an atomic layer deposition (ALD) or chemical vapor deposition (CVD) process. The gate insulating pattern 111P may be formed along the upper surface of the substrate 100, the sidewall of the gate trench GT, and the bottom surface GT_BS of the gate trench GT. For example, the gate insulating pattern 111P may be formed on the element isolation film 105. The gate insulating pattern 111P may include, for example, at least one of silicon oxide, silicon nitride, silicon oxynitride, or a high dielectric constant material with a higher dielectric constant than that of silicon oxide.

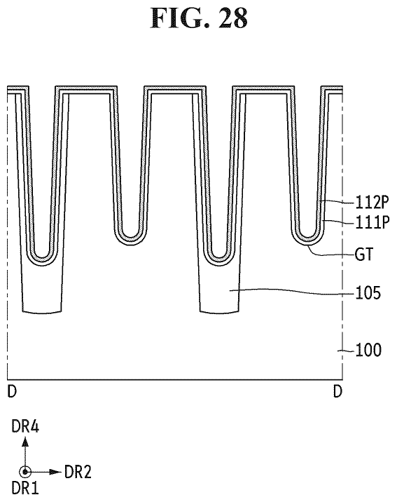

Referring to FIG. 28, a gate conductive pattern 112P may be formed on the gate insulating pattern 111P. More specifically, the gate conductive pattern 112P may be formed along a profile of the gate insulating pattern 111P. The gate conductive pattern 112P may be formed using an atomic layer deposition (ALD) or chemical vapor deposition (CVD) process. The gate conductive pattern 112P may include one of titanium nitride (TiN), molybdenum nitride (MoN), tungsten nitride (WN), and tantalum nitride (TaN).

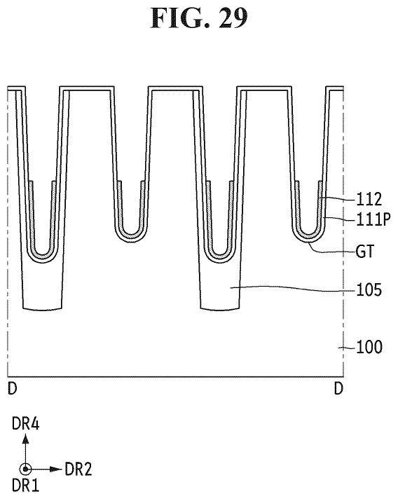

Referring to FIG. 29, an etch-back process may be performed on the gate conductive pattern 112P. The etch-back process on the gate conductive pattern 112P may be performed as an in-situ process in a process of forming the gate electrode pattern 113, which will be described later. At least a portion of the gate conductive pattern 112P may be removed through the etch-back process on the gate conductive pattern 112P. At least a portion of the gate conductive pattern 112P on the gate insulating pattern 111P may be removed to form the gate conductive film 112.

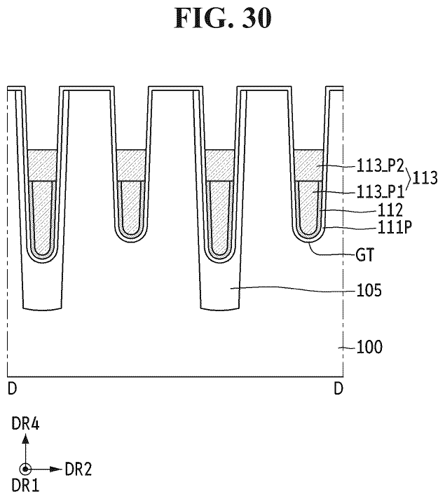

Referring to FIG. 30, the gate electrode pattern 113 may be formed on the gate insulating pattern 111P and the gate conductive film 112. The gate electrode pattern 113 may be formed using a bottom-up growth method. The bottom-up growth method may include, for example, a selective growth method. The selective growth method may be, for example, a method of selectively depositing a conductive material on a conductive material. The conductive material capable of the selective growth may include, for example, one of cobalt (Co), tungsten (W), and molybdenum (Mo), which may allow a selectivity between the conductive material and the insulating material to be secured.

As the gate electrode pattern 113 is formed using the bottom-up growth method, the crystal orientation CX1_DR of the first conductive material crystal 113_CX1 included in the first portion 113_P1 of the gate electrode pattern 113 may be the second direction DR2, while the crystal orientation CX2_DR of the second conductive material crystal 113_CX2 included in the second portion 113_P2 of the gate electrode pattern 113 may be the fourth direction DR4, as shown in FIG. 9. Even when the first portion 113_P1 of gate electrode pattern 113 and the second portion 113_P2 of gate electrode pattern 113 include the same conductive material, the boundary between the first portion 113_P1 of the gate electrode pattern 113 and the second portion 113_P2 of the gate electrode pattern 113 may be clearly defined. Because the crystal orientation CX1_DR of the first conductive material crystal 113_CX1 included in the first portion 113_P1 of the gate electrode pattern 113 is distinct from the crystal orientation CX2_DR of the second conductive material crystal 113_CX2 included in the second portion 113_P2 of the gate electrode pattern 113, the boundary between the first portion 113_P1 of the gate electrode pattern 113 and the second portion 113_P2 of the gate electrode pattern 113 may be clearly defined.

The boundary between the first portion 113_P1 of the gate electrode pattern 113 and the second portion 113_P2 of the gate electrode pattern 113 is shown to be coplanar with the upper surface 112_US of the gate conductive film 112. This is only for convenience of illustration, and embodiments are not limited thereto. For example, based on the upper surface of the substrate 100, a vertical level of a portion of the boundary between the first portion 113_P1 of the gate electrode pattern 113 and the second portion 113_P2 of the gate electrode pattern 113 may be higher or lower than a vertical level of the upper surface 112_US of the gate conductive film 112.

A vertical level of the boundary between the first portion 113_P1 of the gate electrode pattern 113 and the second portion 113_P2 of the gate electrode pattern 113 may be lower than a vertical level of the upper surface 112_US of the gate conductive film 112. In this case, the semiconductor memory device as described above using FIGS. 20 to 23 may be manufactured.

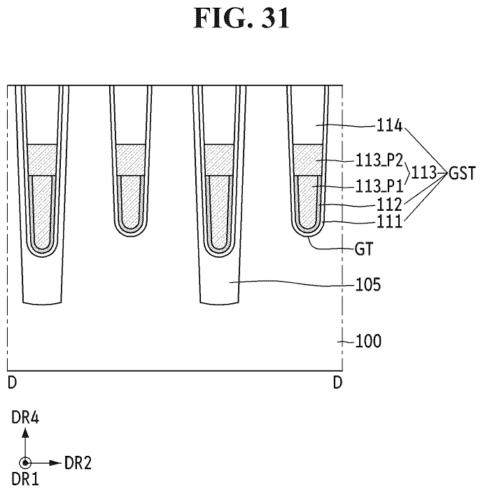

Referring to FIG. 31, a gate capping pattern may be formed on the gate insulating pattern 111P and the gate electrode pattern 113. The gate capping pattern may fill a portion of the gate trench GT remaining after the gate insulating pattern 111P, the gate conductive film 112, and the gate electrode pattern 113 have been formed therein.

The gate capping film 114 may be formed by performing a planarization process on the upper surface of the substrate 100. The gate capping film 114 may be formed by removing a portion of the gate capping pattern on the gate insulating pattern 111P during the planarization process. The gate capping film 114 may include one of a silicon nitride film, a silicon oxide film, and a silicon oxynitride film.

The gate insulating film 111 may be formed by performing a planarization process on the upper surface of the substrate 100. The gate insulating film 111 may be formed by removing a portion of the gate insulating pattern 111P on the upper surface of the substrate 100 during the planarization process. The gate insulating film 111 may include silicon oxide.

The gate structure GST may be formed by performing a planarization process on the upper surface of the substrate 100. The gate structure GST may include the gate insulating film 111, the gate conductive film 112, the gate electrode pattern 113, and the gate capping film 114. The gate electrode pattern 113 may correspond to the word-line WL.

While aspects of embodiments have been particularly shown and described, it will be understood that various changes in form and details may be made therein without departing from the spirit and scope of the following claims.

What is claimed is:

1. A semiconductor memory device comprising:
a substrate comprising an element isolation film and an active area defined by the element isolation film; and
a gate structure provided in a gate trench in the substrate which extends across the element isolation film and the active area in a first direction;
wherein the gate structure comprises:
a gate insulating film extending along the gate trench;
a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; and
a gate electrode pattern in the gate recess and contacting the upper surface of the gate conductive film,
wherein the gate electrode pattern comprises a first portion in the gate recess, and a second portion on the first portion of the gate electrode pattern,
wherein the second portion of the gate electrode pattern is in contact with the upper surface of the gate conductive film,
wherein the first portion of the gate electrode pattern comprises a plurality of first conductive material crystals having a crystal orientation corresponding to a second direction, and
wherein the second portion of the gate electrode pattern comprises a plurality of second conductive material crystals having a crystal orientation corresponding to a third direction.

2. The semiconductor memory device of claim 1, wherein the second portion of the gate electrode pattern comprises an upper surface and a bottom surface opposite to each other in the third direction, and
wherein the upper surface of the second portion of the gate electrode pattern and the bottom surface of the second portion of the gate electrode pattern are defined by the plurality of second conductive material crystals.

3. The semiconductor memory device of claim 2, wherein at least one of the plurality of second conductive material crystals extends from the bottom surface of the second portion of the gate electrode pattern to the upper surface of the second portion of the gate electrode pattern.

4. The semiconductor memory device of claim 1, wherein the plurality of first conductive material crystals have a first average crystal grain size in the second direction,
wherein the plurality of second conductive material crystals have a second average crystal grain size in the third direction, and
wherein the second average crystal grain size is greater than the first average crystal grain size.

5. The semiconductor memory device of claim 4, wherein the second average crystal grain size is at least three times greater than the first average crystal grain size.

6. The semiconductor memory device of claim 1, wherein a vertical length in the third direction between a bottom surface of the substrate and the bottom surface of the gate trench in the element isolation film is less than a vertical length in the third direction between the bottom surface of the substrate and the bottom surface of the gate trench in the active area.

7. The semiconductor memory device of claim 1, wherein the first portion of the gate electrode pattern comprises an upper surface in contact with the second portion of the gate electrode pattern, and
wherein a vertical length in the third direction between the bottom surface of the gate trench and the upper surface of the first portion of the gate electrode pattern is less than a vertical length in the third direction between the bottom surface of the gate trench and the upper surface of the gate conductive film.

8. The semiconductor memory device of claim 1, wherein the gate conductive film comprises any one of titanium nitride, molybdenum nitride, tungsten nitride, and tantalum nitride.

9. The semiconductor memory device of claim 1, wherein the plurality of first conductive crystal material crystals and the plurality of second conductive material crystals comprise a common conductive material.

10. The semiconductor memory device of claim 9, wherein the common conductive material comprises any one of cobalt (Co), tungsten (W), and molybdenum (Mo).

11. The semiconductor memory device of claim 1, further comprising a gate capping film on the second portion of the gate electrode pattern.

12. A semiconductor memory device comprising:
a substrate comprising an element isolation film and an active area defined by the element isolation film; and
a gate structure in a gate trench in the substrate which extends across the element isolation film and the active area in a first direction;
wherein the gate structure comprises:
a gate insulating film extending along the gate trench;
a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film; and
a gate electrode pattern in the gate recess and contacting the upper surface of the gate conductive film,
wherein the gate electrode pattern comprises a first portion in the gate recess, and a second portion on the first portion of the gate electrode pattern,
wherein the second portion of the gate electrode pattern is in contact with the upper surface of the gate conductive film,
wherein the first portion of the gate electrode pattern comprises a plurality of first conductive material crystals stacked in a second direction, and
wherein the second portion of the gate electrode pattern comprises a plurality of second conductive material crystals arranged in a third direction.

13. The semiconductor memory device of claim 12, wherein a height in the second direction of the second portion of the gate electrode pattern is equal to a height in the second direction of at least one of the plurality of second conductive material crystals.

14. The semiconductor memory device of claim 12, wherein the plurality of first conductive material crystals have a first average crystal grain size in the third direction,
wherein the plurality of second conductive material crystals have a second average crystal grain size in the second direction, and
wherein the second average crystal grain size is at least three times greater than the first average crystal grain size.

15. The semiconductor memory device of claim 12, wherein the first portion of the gate electrode pattern comprises an upper surface in contact with the second portion of the gate electrode pattern, and
wherein a vertical length in the second direction between the bottom surface of the gate trench and the upper surface of the first portion of the gate electrode pattern is less than a vertical length in the second direction between the bottom surface of the gate trench and the upper surface of the gate conductive film.

16. The semiconductor memory device of claim 12, wherein the gate conductive film comprises any one of titanium nitride, molybdenum nitride, tungsten nitride, and tantalum nitride.

17. The semiconductor memory device of claim 12, wherein the first portion of the gate electrode pattern and the second portion of the gate electrode pattern comprise a common conductive material, and
wherein the common conductive material comprises any one of molybdenum (Mo), tungsten (W), and cobalt (Co).

18. A semiconductor memory device comprising:
a substrate comprising an active area defined by an element isolation film, wherein the active area extends in a first direction, and comprises a first portion, and second portions respectively defined on opposite sides of the first portion;
a word-line in the substrate and the element isolation film, wherein the word-line extends in a second direction different from the first direction across an area between the first portion of the active area and one of the second portions of the active area;
a bit-line contact connected to the first portion of the active area;
a bit-line on the bit-line contact and connected to the bit-line contact, wherein the bit-line extends in a third direction different from the first direction and the second direction;
a storage contact connected to one of the second portions of the active area;
a landing pad on the storage contact and connected to the storage contact; and
a capacitor on the landing pad and connected to the landing pad,
wherein the word-line comprises a gate structure in a gate trench,
wherein the gate structure comprises:
a gate insulating film extending along the gate trench;
a gate conductive film on the gate insulating film and defining a gate recess, wherein a vertical length between a bottom surface of the gate trench and an upper surface of the gate conductive film is less than a vertical length between the bottom surface of the gate trench and an upper surface of the gate insulating film;
a gate electrode pattern in the gate recess and contacting the upper surface of the gate conductive film; and
a gate capping film on the gate electrode pattern,
wherein the gate electrode pattern comprises a first portion in the gate recess, and a second portion on the first portion of the gate electrode pattern,
wherein the second portion of the gate electrode pattern is in contact with the upper surface of the gate conductive film,
wherein the first portion of the gate electrode pattern comprises a plurality of first conductive material crystals having a crystal orientation corresponding to the third direction, and
wherein the second portion of the gate electrode pattern comprises a plurality of second conductive material crystals having a crystal orientation corresponding to a fourth direction.

19. The semiconductor memory device of claim 18, wherein the plurality of first conductive material crystals have a first average crystal grain size in the third direction,
wherein the plurality of second conductive material crystals have a second average crystal grain size in the fourth direction, and
wherein the second average crystal grain size is at least three greater than the first average crystal grain size.

20. The semiconductor memory device of claim 18, wherein the plurality of first conductive material crystals and the plurality of second conductive material crystals comprise a common conductive material, and
wherein the common conductive material comprises any one of molybdenum (Mo), tungsten (W), and cobalt (Co).
